(19) United States
(12) Patent Application Publication
(10) Pub. No.: US 2011/0103026 A1
(43) Pub. Date: May 5, 2011

(54) MOUNTING APPARATUS FOR PERIPHERAL COMPONENT INTERCONNECT CARD

(75) Inventors: WEN-HU LU, Shenzhen City (CN); YA-NI ZHANG, Shenzhen City (CN); YI-LUNG CHOU, Tu-Cheng (TW)

(73) Assignees: Hong Fu Jin Precision Industry (ShenZhen) Co.,Ltd., Shenzehen City (TW); Hon Hai Precision Industry Co., Ltd., Tu-Cheng (TW)

(21) Appl. No.: 12/713,277

(22) Filed: Feb. 26, 2010

(30) Foreign Application Priority Data
Nov. 4, 2009 (CN) 200920314047.X

(51) Int. Cl. H05K 7/00

(52) U.S. Cl. 361/748

(57) ABSTRACT

A mounting apparatus for a PCI card includes a mounting bracket, a mounting piece for attaching the PCI card to the mounting bracket, and a securing member. The mounting bracket has a blocking plate and a first engaging portion. The mounting piece includes an elongated body and a mounting end extending from the elongated body. The mounting end abuts the blocking plate. The securing member is pivotably attached to the mounting bracket and abuts the mounting end to sandwich the mounting end between the securing member and the blocking plate. The securing member includes a second engaging portion, a handling portion, and an elastic arm. The second engaging portion engages the first engaging portion. The handling portion is for driving the second engaging portion to disengage from the first engaging portion by biasing the handling portion.

### BACKGROUND

1. Technical Field

The disclosure generally relates to mounting apparatuses, especially to a mounting apparatus for a peripheral component interconnect (PCI) card.

2. Description of Related Art

PCI cards are widely used in computers. PCI is a sort of bus structure, which is used for connecting to modem cards, monitor cards, sound cards or other peripheral equipment. The conventional manner for mounting PCI cards usually involves screws. Such a manner not only requires screws but also a screwdriver, which is time-consuming and troublesome. Moreover, the screws are easily lost. If a screw falls on the printed circuit board (PCB), damage to the PCB may occur, especially when the computer is powered up. Furthermore, more and more components are needed to be installed in the computer. The space in the computer enclosure will be occupied by a large number of electronic components making the space too cramped for operating a screwdriver.

### BRIEF DESCRIPTION OF THE DRAWINGS

FIG. 1 is an exploded, isometric view of an exemplary embodiment of a mounting apparatus for PCI cards.

FIG. 2 is an enlarged isometric view of a securing member of FIG. 1, but viewed from another aspect.

FIG. 3 is an enlarged isometric view of a securing member of FIG. 1.

FIG. 4 is a pre-assembled view of FIG. 1.

FIG. 5 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

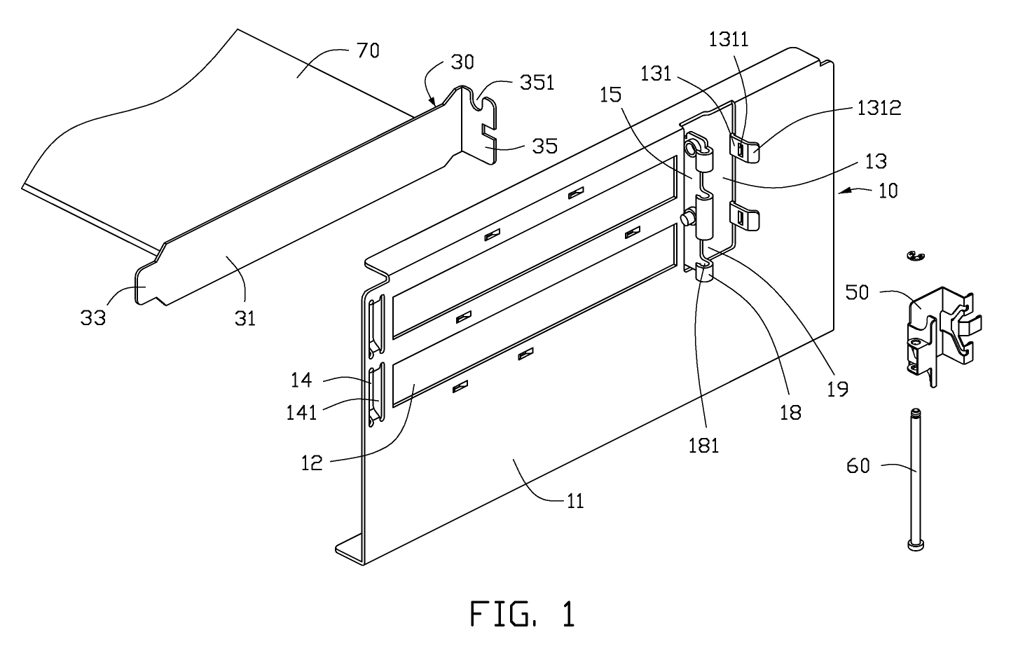

FIG. 1 depicts an exemplary embodiment of a mounting apparatus for a PCI card 70. In the exemplary embodiment, a PCI card 70 is used as illustration. The mounting apparatus includes a mounting bracket 10, a mounting piece 30 mounted to the PCI cards 70, and a securing member 50 pivotally mounted to the mounting bracket 10.

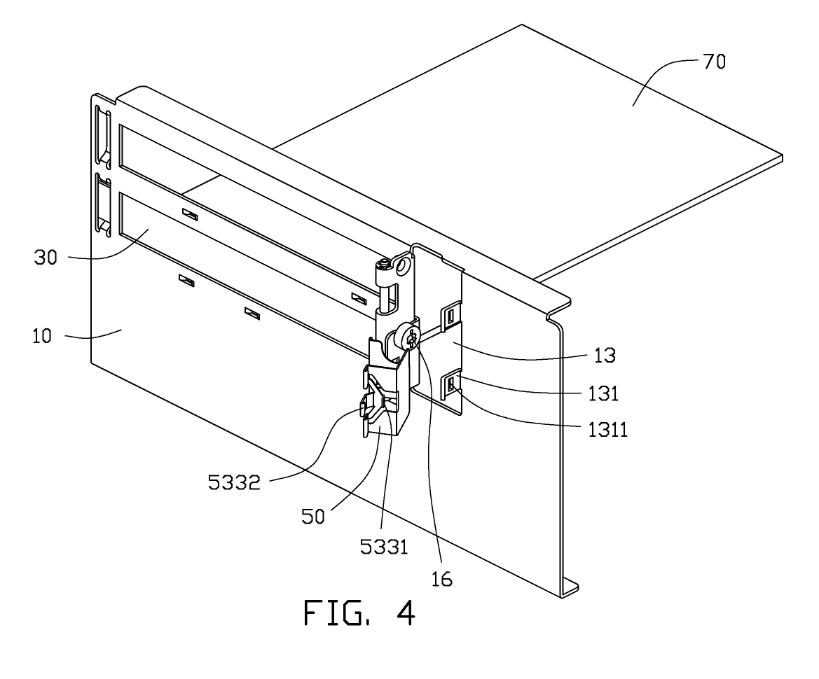

The mounting bracket 10 includes a base 11. Two elongated rectangular slots 12 are defined in the base 11. Two bridge portions 14 are formed on the base 11 adjacent to one side of the elongated rectangular slots 12. Each bridge portion 14 defines a securing slot 141. A mounting opening 13 is defined in the base 11 adjacent to the elongated rectangular slots 12. A blocking plate 15, perpendicular to the base 11, extends from a side edge of the mounting opening 13 adjacent to the elongated rectangular slots 12. A positioning protrusion 16 (shown in FIG. 4) protrudes from the blocking plate 15. A plurality of pivoting portions 18 are formed at a distal edge of the blocking plate 15. Each pivoting portion 18 defines a pivoting hole 181. A receiving notch 19 is defined between every two adjacent pivoting portions 18. Two first engaging portions 131 protrude from the other side edge of the mounting opening 13 opposite to the blocking plate 15. Each first engaging portion 131 defines a securing hole 1311. Each first engaging portion 131 includes a distal end 1312 obliquely extending from the first engaging portion 131.

The mounting piece 30 includes an elongated body 31, an inserting end 33, and a mounting end 35. The elongated body 31 is for covering the corresponding elongated rectangular slot 12. The inserting end 33 extends from one side of the elongated body 31 and is for insertion in the securing slot 141. The mounting end 35 extends from the other side of the elongated body 31. A cutout 351 is defined in an edge of the mounting end 35.

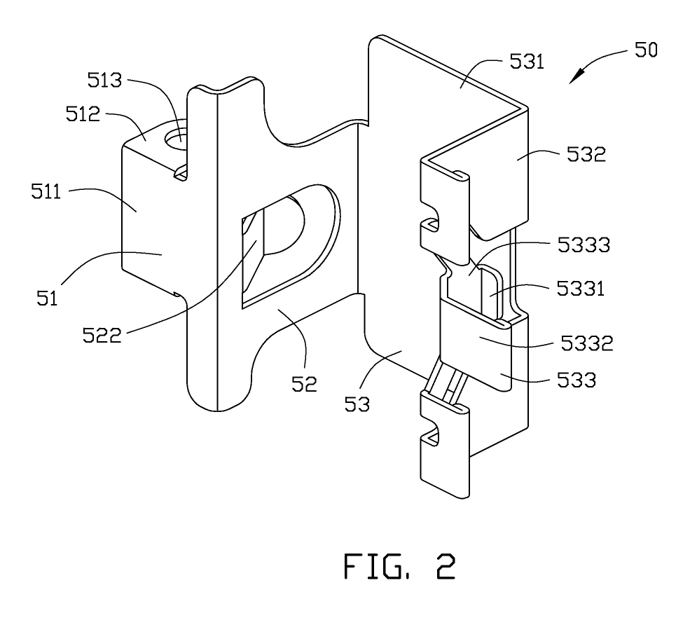

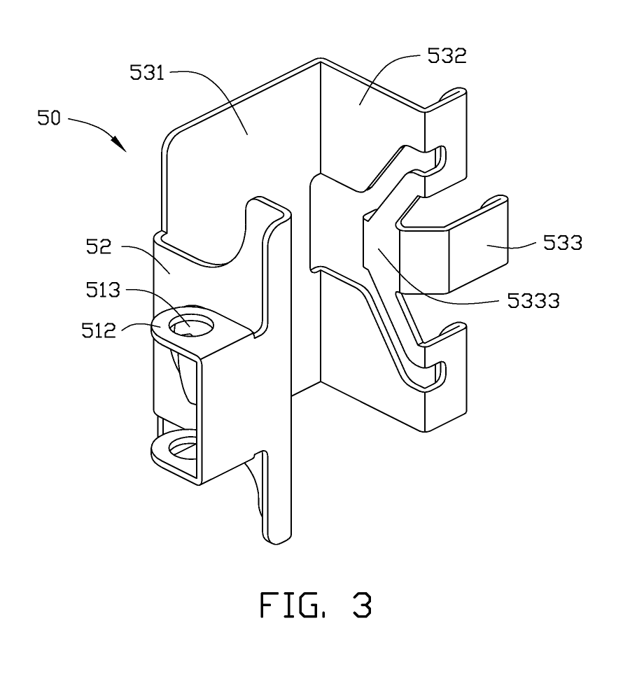

Referring to FIGS. 2 and 3, the securing member 50 includes a pivoting portion 51, a pressing portion 52, and a mounting portion 53. The pressing portion 52 extends from the pivoting portion 51 and the mounting portion 53 extends from the pressing portion 52. The securing member 50 is generally U-shaped.

The pivoting portion 51 includes a body 511, two pivoting tabs 512 extending from two opposite sides of the body 511. Each pivoting tab 512 defines a pivoting hole 513.

The pressing portion 52 includes an elastic tab 522 protruding out from the pressing portion 52. The elastic tab 522 is for elastically resisting the mounting end 35 of the mounting piece 30.

The mounting portion 53 includes a connecting plate 531 connected to the pressing portion 52, two supporting plates 532 extending from the connecting plate 531, and a securing portion 533 connected to the supporting plate 532. The securing portion 533 includes a second engaging portion 5331, a handling portion 5332, and an elastic arm 5333 connecting the second engaging portion 5331 and the handling portion 5332. In an exemplary embodiment, the second engaging portion 5331 is a securing tab. The elastic arm 5333 is generally V-shaped. The handling portion 5332 and the second engaging portion 5331 extend from two opposite sides of the elastic arm 5333 in a first direction. The elastic arm 5333 is connected to the two supporting plates 532 in a second direction generally perpendicular to the first direction. The second engaging portion 5331 is perpendicular to the elastic arm 5333. The handling portion 5332 can drive the second engaging portion 5331 to move by biasing the handling portion 5332.

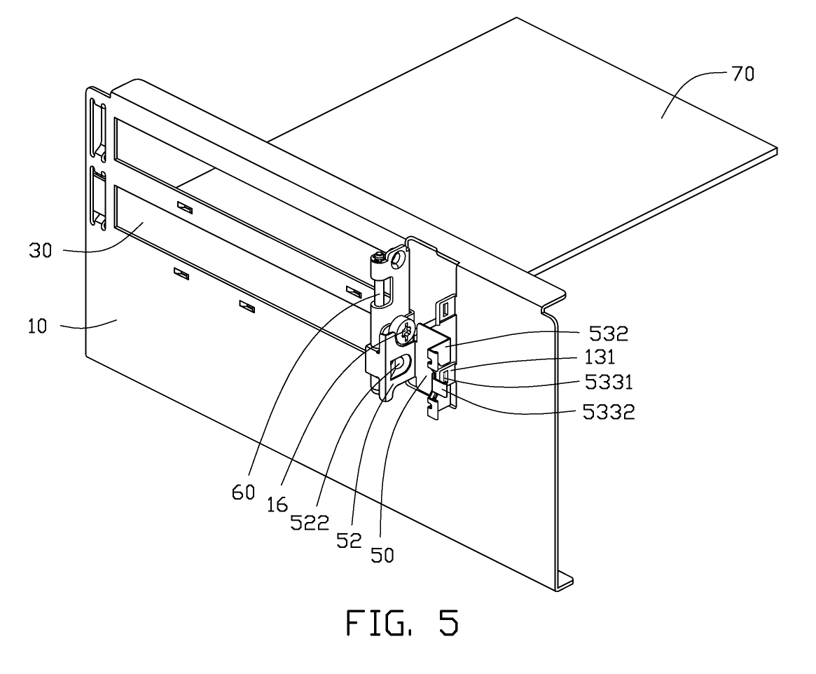

Referring to FIGS. 1 to 5, in assembly, the elongated body 31 of the mounting piece 30 covers the corresponding elongated rectangular slot 12. The inserting end 33 of the mounting piece 30 is inserted in the securing slots 141 and the mounting end 35 of the mounting piece 30 abuts the blocking plate 15 by the mounting opening 13. The positioning protrusion 16 is received in the cutout 351 of the mounting piece 30. The pivoting portion 51 of the securing member 50 is received in the receiving notch 19. A pivoting fastener 60 is inserted in the pivoting holes 181 and the pivoting holes 513 to pivotally attach the securing member 50 to the base 11 of the mounting bracket 10. Then, the securing member 50 is pivoted towards the base 11. The second engaging portion 5331 of the securing member 50 resists against and deforms the distal end 1312 of the first engaging portion 131 to move away from securing member 50 until the second engaging portion 5331 of the securing member 50 engages the securing hole 1311 of the first engaging portion 131. The securing members 50 are securely mounted on the mounting bracket 10. The elastic tab 522 is elastically deformed and resists the mounting end 35 of the mounting piece 30.

In disassembly, the handling portion 5332 of the securing member 50 is pressed to bias the elastic arm 5333. The elastic arm 5333 drives the second engaging portion 5331 to disengage from the securing hole 1311 of the first engaging portion 131. Then, the securing member 50 is pivoted away from the mounting bracket 10. The elastic tab 522 restores to an original state. Thus, the PCI card 70 can be easily removed from the mounting bracket 10.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus for a PCI card, comprising:
a mounting bracket having a blocking plate and a first engaging portion;
a mounting piece for attaching the PCI card to the mounting bracket, the mounting piece comprising an elongated body and a mounting end extending from the elongated body, the mounting end abutting the blocking plate; and
a securing member pivotably attached to the mounting bracket and abutting the mounting end to sandwich the mounting end between the securing member and the blocking plate, the securing member comprising a second engaging portion, a handling portion, and an elastic arm, the second engaging portion engaging the first engaging portion, the handling portion for driving the second engaging portion to disengage from the first engaging portion by biasing the handling portion.

2. The mounting apparatus for a PCI card of claim 1, wherein the securing member comprises a first pivoting portion, a pressing portion extending from the first pivoting portion, and a mounting portion extending from the pressing portion, the pivoting portion pivotably attached to the mounting bracket, the pressing portion abutting the mounting end, the mounting portion comprising the second engaging portion, the handling portion, and the elastic arm.

3. The mounting apparatus for a PCI card of claim 2, wherein the second engaging portion and the handling portion extending respectively from two opposite sides of the elastic arm in a first direction, and the mounting portion further comprises two supporting plates and a connecting plate, the elastic arm connecting the two supporting plates in a second direction generally perpendicular to the first direction, the pressing portion connected to the two supporting plates by the connecting plate.

4. The mounting apparatus for a PCI card of claim 3, wherein the securing member is generally U-shaped.

5. The mounting apparatus for a PCI card of claim 2, wherein the pressing portion comprises an elastic tab abutting the mounting end.

6. The mounting apparatus for a PCI card of claim 2, wherein the first pivoting portion comprises a body and two pivoting tabs extending from two opposite sides of the body, each tab defining a pivoting hole; the blocking plate comprises a second pivoting portion, the second pivoting portion defines a second pivoting hole corresponding to the first pivoting hole.

7. The mounting apparatus for a PCI card of claim 1, wherein the first engaging portion defines a securing hole, and the second engaging portion has a securing tab for engaging the securing hole.

8. The mounting apparatus for a PCI card of claim 7, wherein the first engaging portion comprises a distal end obliquely extending from the first engaging portion, the distal end for guiding the securing tab to engage the securing hole.

9. The mounting apparatus for a PCI card of claim 1, wherein the elastic arm is generally V-shaped.

10. A mounting apparatus for a PCI card, comprising:
a mounting bracket having a slot, a blocking plate adjacent to the slot, and a first engaging portion;
a mounting piece for attaching the PCI card to the mounting bracket, the mounting piece comprising an elongated body and a mounting end extending from the elongated body, the elongated body covering the slot, the mounting end abutting the blocking plate of the mounting bracket; and
a securing member comprising a first pivoting portion, a pressing portion extending from the first pivoting portion, and a mounting portion extending from the pressing portion, the pivoting portion pivotably attached to the mounting bracket, the pressing portion abutting the mounting end to sandwich the mounting end between the blocking plate and the pressing portion, the mounting portion comprising a second engaging portion, a handling portion, and an elastic arm, the second engaging portion and the handling portion extending from two opposite sides of the elastic arm in a first direction, the elastic arm connected to the mounting portion in a second direction generally perpendicular to the first direction, the second engaging portion engaging the first engaging portion, the handling portion for driving the second engaging portion to disengage from the first engaging portion by biasing the handling portion.

11. The mounting apparatus for a PCI card of claim 10, wherein the mounting portion further comprises two supporting plates and a connecting plate, the elastic arm connected to the two supporting plates in the second direction, the pressing portion connected to the two supporting plates by the connecting plate.

12. The mounting apparatus for a PCI card of claim 11, wherein the securing member is generally U-shaped.

13. The mounting apparatus for a PCI card of claim 10, wherein the first engaging portion defines a securing hole, and the second engaging portion has a securing tab for engaging the securing hole.

14. The mounting apparatus for a PCI card of claim 10, wherein the first engaging portion comprises a distal end obliquely extending from the first engaging portion, the distal end is for guiding the securing tab to engage the securing hole.

15. The mounting apparatus for a PCI card of claim 10, wherein the elastic arm is generally V-shaped.

16. The mounting apparatus for a PCI card of claim 10, wherein the pressing portion comprises an elastic tab abutting the mounting end.

17. The mounting apparatus for a PCI card of claim 10, wherein the first pivoting portion comprises a body and two pivoting tabs extending from two opposite sides of the body, each tab defining a pivoting hole; the blocking plate comprises a second pivoting portion, the second pivoting portion defines a second pivoting hole corresponding to the first pivoting hole.

18. The mounting apparatus for a PCI card of claim 10, wherein the securing member is disposed between the blocking plate and the first engaging portion.
